(19) United States
(12) Patent Application Publication
(10) Pub. No.: US 2010/0052805 A1
(43) Pub. Date: Mar. 4, 2010

(54) HIGH-MODE SELF-OSCILLATING PULSE MODULATOR

(75) Inventors: Kim Rishoj Pedersen, Ega (DK); Lars Arknaes-Pedersen, Viby (DK)

Correspondence Address: CANTOR COLBURN, LLP, 20 Church Street, 22nd Floor, Hartford, CT, 06103, US

(73) Assignee: TC GROUP A/S, Risskov (DK)

(21) Appl. No.: 12/373,403

(22) PCT Filed: Jul. 11, 2006
(86) PCT No.: PCT/DK2006/000408

§ 371 Date: Jun. 23, 2009

(51) Int. Cl. H03K 7/08

(52) U.S. Cl. 332/109

(57) ABSTRACT

The invention relates to a high-mode self-oscillating pulse modulator. According to the invention, a complete rethinking of preconditions for oscillation and modulation in an oscillating modulator as all conventional thinking of how to apply oscillation in a modulator has been set aside. Thus, according to the invention, high-mode oscillation refers to an oscillation at a higher mode than the first mode, which is conventionally regarded as the one and only applicable mode in an oscillating modulator.

### FIELD OF THE INVENTION

The invention relates to a self-oscillating pulse modulator according to claim 1.

### BACKGROUND OF THE INVENTION

A pulse modulator is a central element of many power conversion systems. Most switching power converters are based on Pulse Width Modulation (PWM) as means to control efficient conversion between domains (DC or AC). Pulse modulators are broadly applied in several contexts, low-power conversion contexts included.

Within the field of e.g. PWM a typical converter may include a PWM modulator, a filter and a control system. A prior art system of this type is described in U.S. Pat. No. 4,724,396 and by Mr. Attwood in Journal of the AES, November 1983. p. 842-853. However, PWM has a range of shortcomings also well known to the art, mainly due to the implementation of the carrier generation. This limits the system bandwidth and complicates design. Also, a stable and robust control system design is difficult.

In order to overcome the limitations of this type of modulators, modified versions of pulse width modulators have been introduced. These modulators generally benefit from the fact that the switching rate of the modulator is established by an oscillation in a non-linearity in the forward path of the modulator together with a feedback loop arrangement.

An example of such a pulse width modulator applied in connection with a switching power stage is e.g. described and explained in PCT/DK97/00497. One of the features of such a modulator is that the need for a carrier signal is eliminated.

A problem related to a pulse width modulator of the above-mentioned type is, however, that the switching rate and the effective feedback loops arrangement are mutually constrained. Such constraining may e.g. be counteracted partly by complex filter topologies or e.g. application of a relatively high switching rate. This restriction leads to different quite complex considerations with respect to the loop filter and moreover a restriction with respect to the effective suppression of errors in the oscillating modulator.

### SUMMARY OF THE INVENTION

The invention relates to a high-mode self-oscillating pulse modulator.

According to the invention, a complete rethinking of preconditions for oscillation and modulation in an oscillating modulator as all conventional thinking of how to apply oscillation in a modulator has been set aside. Thus, according to the invention, high-mode oscillation refers to an oscillation at a higher mode than the first mode, which is conventionally regarded as the one and only applicable mode in an oscillating modulator.

A self-oscillating pulse modulator designates in general a pulse modulator wherein a non-linearity of the pulse modulator is included in the oscillating circuitry. This technique is generally a counterpart to conventional modulation where a modulation is related to a specific separately added modulation signal. An example of such technique is a pulse width modulator where an input signal is modulated with respect to a carrier signal, e.g. a square or triangle reference wave signal.

A self-oscillating pulse modulator may furthermore include lock or synchronization means in order to control or at least maintain the frequency of the modulator oscillation.

Different methods of designating oscillating modulators have been suggested in the prior art. Thus, some refer to an oscillating modulator as a self-oscillating modulator and some refer to the modulators as controlled oscillating modulators (COM).

Generally, according to the provisions of the present invention it may be said that the modulator itself is a part of an oscillating circuitry and that the established oscillating circuitry in turn forms an essential part of the modulator.

A further advantageous feature of a high-mode pulse modulator according to the invention is that the switching characteristics may be designed and determined relatively freely with few restrictions. As an example, the main switching frequency may be obtained by a proper design of a filter arrangement of the loop. In other words, a high-mode oscillator offers high suppression of errors together with a freedom, by proper design of filter characteristics, to choose and obtain the desired mode of operation e.g. with the same hardware structure as a conventional self-oscillating modulator.

In an embodiment of the invention, the pulse modulator comprises an active pulse modulator.

According to a preferred embodiment of the invention, a pulse modulator designates that the modulator and the oscillator is established as circuit comprising of discrete elements. Evidently, such discrete elements may comprise elements of a digital implementation and also analog components. Generally, such circuit may be regarded to be active in contrast to e.g. conventional mechanical oscillators.

Moreover, it should furthermore be noted that a pulse modulator according to the invention may or may not feature further simultaneous modes or at least further harmonics, etc. as long as the main aim is obtained, namely a desired modulation.

In an embodiment of the invention, the oscillating modulator is a pulse width modulator.

According to a preferred embodiment of the invention, the modulator is a pulse width modulator (PWM).

In this context it should be noted that PWM covers several different types of variations, such as NPWM, LPWM, etc. A PWM of an embodiment of the invention utilizes a very broad banded feedback as error attenuation combined with the PWM modulation of the input signal. Evidently, according to the invention, several other self-oscillating topologies may be applied within the scope of the invention with further signal paths.

According to an embodiment of the invention, an oscillation mode refers to the order of zero crossing of the phase margin or alternatively the crossing of the 360° phase shift of the open loop oscillator filter. In other words, the first zero crossing may be referred to as a first mode, the second zero crossing may be referred to as a second mode and so forth.

Thus, a third mode oscillating pulse width modulator according to an embodiment of the invention features an oscillation defined by the third zero crossing.

In an embodiment of the invention, the pulse width modulator is a mode two or mode three oscillator.

According to an advantageous embodiment of the invention, an oscillation is established in the transition where the phase margin of the modulator oscillator goes from positive to negative at the first mode or second mode above the fundamental mode, namely the second or third mode. Operation in this mode features an advantageous resulting loop gain in the utility band of the modulator at a desired switch frequency.

In an embodiment of the invention, the high mode margin is less than 800 kHz, preferably less than 500 kHz and most preferably less than 400 kHz.

In an embodiment of the invention, the high mode margin is less than 75% of the switch frequency at a switching frequency of at least 10 kHz.

In an embodiment of the invention, the high mode margin is less than 75% of the switch frequency at a switching frequency of at least 200 kHz

In an embodiment of the invention, the high mode margin is less than 50% of the switch frequency at a switching frequency of at least 200 kHz

In an embodiment of the invention, the high mode margin is less than 25% of the switch frequency at a switching frequency of at least 200 kHz

According to a preferred embodiment of the invention a high mode margin should be not more than 25% at a switch frequency of higher than 200 kHz in order to obtain very advantageous modulator properties in high-demanding applications such as audio applications.

In an embodiment of the invention, the oscillating modulator comprises an input, an output, at least one forward path and at least one feedback path,

said at least one forward path comprising at least one non-linearity,
said at least one feedback path comprising a loop-filter arrangement
said oscillating modulator having a switching frequency which is established on the basis of oscillation in said at least non-linearity and said loop-filter arrangement, wherein said switching frequency is established at the second or higher zero crossing of the phase margin of the open loop filter.

According to the invention, a switch frequency is obtained at a frequency higher than conventional self-oscillating modulators thereby obtained a steep slope of the effective loop filter as the effective filter order of the loop filter may be increased without requiring that the first zero order crossing defines the switch frequency.

An important prerequisite of the invention is that the conventional requirements with respect to the above-described first zero crossing, i.e. the requirement of maintaining a positive phase margin may be disregarded while still maintaining a stable pulse width modulator.

The general principle of allowing oscillation at a zero crossing of the phase margin of the open loop filter may be advantageously applied e.g. in the analog domain e.g. in connection with a power switching amplifier or in the digital domain—or in the transition between the analog and the digital domain—in connection with e.g. an A/D-converter.

A loop-filter arrangement will, according to the claimed invention, generally refer to any electrical conversion performed between the output and the input of the non-linearity in the feedback path. Thus, the loop-filter arrangement may comprise a dedicated loop filter designed according to predefined specifications in one or several paths or even further non-linearities and moreover the loop-filter arrangement may include different physical properties of the feedback path in its complete extent reflecting the non-ideal properties of the involved components or signal processing properties.

The at least one non-linearity may comprise any suitable non-linear digital or analog section or circuit and may e.g. comprise a comparator, a hysteresis section of circuit, a limiter or any combination thereof.

In an embodiment of the invention, said loop filter has a negative phase margin.

In an embodiment of the invention, the oscillating modulator comprises an input, an output, at least one forward path and at least one feedback path,

said at least one forward path comprising at least one non-linearity,
said at least one feedback path comprising a loop-filter arrangement,
said modulator further comprising a lock signal generator or a lock signal input,
said oscillating modulator having a switching frequency which is established on the basis of oscillation in said at least non-linearity and said loop-filter arrangement combined with a lock signal generated by said lock signal generator or a lock signal input.

In an embodiment of the invention, the pulse modulator comprises a mode-selector.

According to an embodiment of the invention, a mode selector may be applied in connection with e.g. start-up, to ensure that the desired mode is reached.

In an embodiment of the invention, the pulse modulator comprises mode locking means.

According to an embodiment of the invention, mode locking means may be applied for the purpose of maintaining the oscillation of the pulse modulator in the desired mode. In many contexts such mode locking means should simply ensure that a pulse modulator returns to the desired mode if sudden mode changes occur. In other contexts such mode locking means may imply preventing occurrence of undesired modes.

Mode locking means may e.g. comprise mode-canceling means, i.e. filtering means, linear or non-linear removing specific components at one or several undesired modes in order to prevent an oscillation.

Typically, an oscillation should be obtained at one only in order to obtain the desired modulation and noise suppression.

In an embodiment of the invention mode locking means comprises a mode selector controlled at least partly by a mode detector.

According to an embodiment of the invention, mode locking means may be applied for the purpose of maintaining the pulse-modulator oscillation in the desired mode by a continuous monitoring of the mode by the mode detector. If a mode change occurs or is expected to occur a mode selector may be triggered for the purpose of actively returning the pulse modulator to the desired mode or counteracting the undesired drift of the pulse modulator.

In an embodiment of the invention, the pulse modulator is a multimode modulator.

According to an embodiment of the invention, said multimode oscillator is able to switch in at least two different modes. This feature may enable the modulator to switch e.g. in the normal first mode as conventional oscillating modulators and shift into a higher mode when higher quality is desired or required.

According to a further embodiment of the invention, the pulse modulator may comprise a multimode modulating oscillation which may actively, typically automatically according to predefined algorithms, be selected to e.g. minimize the energy consumption under certain conditions and optimize the pulse modulator quality under other conditions.

In an embodiment of the invention, the non-linearity comprises a limiter or a comparator.

According to the invention, a non-linearity is required for obtaining the desired combination of oscillation and modulation as obtained by self-oscillating modulators. Note that the soft-clipping arrangement is also regarded as a limiter and a non-linearity, although the illustrated two clipping levels are basically only reached at infinite. Evidently, several other limiter characteristics may be applied within the scope of the invention.

In an embodiment of the invention, the loop-filter arrangement comprises a loop filter and that the effective order of said loop filter is greater than 2 below switching frequency.

According to an advantageous embodiment of the invention, the order of the loop filter is 2 or greater in the band where such high order offers benefits with respect to error suppression, namely below switching frequency of the pulse modulator.

In an embodiment of the invention, the effective order of said loop filter is 3.

In an embodiment of the invention, the self-oscillating pulse modulator comprises rescue means and mode detecting means and wherein said rescue means suppresses or cancels unwanted modes detected by said mode detecting means.

In an embodiment of the invention, the self-oscillating pulse modulator is digitally implemented.

In an embodiment of the invention, the self-oscillating pulse modulator is implemented as an analog circuit.

According to a very advantageous embodiment of the invention the high mode principles may even be implemented in a analog representation of a the modulator by means of well-known analog components, thereby offering the extreme benefits of the inventions into an analog implementation such as a switching power stage without invoking any significant side-effects into the circuit. This is a significant benefit as analog circuits, as well-known, possesses several non-ideal and limiting properties which may often restrict or make the specific applications impossible compared to their digital counterparts.

Moreover, it has been established that the modulator may even be applied and fully utilized in high voltage or high power applications.

In an embodiment of the invention, the self-oscillating modulator comprises a switching stage.

In an embodiment of the invention, the self-oscillating pulse modulator is applied in audio processing circuitry.

In an embodiment of the invention, the self-oscillating pulse modulator is applied as power pulse width modulator.

In an embodiment of the invention, the modulator comprises means of keeping the switching within a certain range or constant.

A certain drifting of the switching frequency of oscillating modulators may often be observed. The drifting may be accepted in some applications as the drifting has little or in principle no effect on the quality of the modulator. It may, however, be preferred to keep the switching frequency stable in order to prevent e.g. crosstalk.

In an embodiment of the invention, the modulator comprises synchronization means.

The synchronization may e.g. be established by means of reference pulses generator by an oscillator or a pulse generating circuit having the desired switching frequency. Moreover such frequency synchronization may comprise a frequency control which may be a circuit controlling the loop delay, or variants of the embodiment of FIG. 3. Furthermore, the frequency control may comprise a variable loop delay positioned in the signal forward path of the modulator instead of, or in addition to, in the feedback path.

Moreover, the synchronization means may be formed by a combination of added periodic signals and frequency control obtained through control or compensation of modulator loop delay.

In an embodiment of the invention, the modulator forms part of a multi-channel modulator circuitry.

According to an advantageous embodiment of the invention, the oscillating modulator forms part of a multi-channel circuitry, e.g. formed by five or six high-mode oscillating modulators.

In an embodiment of the invention, the modulator forms part of a multi-channel modulator circuitry and wherein the switching frequency of the modulators are synchronized, either in a mutual synchronization or in relation to a common switching frequency reference.

According to an advantageous embodiment of the invention, the oscillating modulator forms part of a multi-channel circuitry, e.g. formed by five or six high-mode oscillating modulators and the modulators are synchronized with respect to switching frequency in order to avoid crosstalk between the different channels of the multi-channel circuitry.

In an embodiment of the invention, the oscillating modulator is implemented as an analog circuit comprising an analog non-linearity and an analog feedback filter.

In an embodiment of the invention, the oscillating modulator is digitally implemented in signal processing circuitry comprising a digitally implemented non-linearity and a digitally feedback filter.

In an embodiment of the invention, the oscillating modulator is implemented as a hybrid digital and analog circuitry.

A hybrid implementation of a high-order modulator may e.g. comprise an A/D converter comprising an analog filter and an analog comparator and an A/D—and a D/A converter as a part of the feedback and forward path.

### THE FIGURES

The invention will now be described with reference to the drawing where

FIG. 1 illustrates a principle model of a self-oscillating pulse modulator,

FIG. 2A-2C illustrate different mode configurations within the scope of the invention,

FIG. 3 illustrates an analog to PCM converter according to an embodiment of the invention,

FIG. 4 illustrates the function of a variable loop delay when applied in the system of FIG. 3,

FIGS. 5 and 6 illustrate the effect of a synchronization signal in a system of FIG. 3,

FIG. 7 illustrates the filter characteristics of FIG. 3,

FIGS. 8 and 9 illustrate when the high-mode modulator is operated in high and low mode respectively in a multimode embodiment of a high-mode modulator according to an embodiment of the invention,

FIG. 10-13 illustrate an applicable loop filter structure and its characteristics of the oscillating circuitry of the modulator within the scope of the invention,

FIG. 14-16 illustrate a further applicable loop filter structure within the scope of the invention,

FIG. 17-20 illustrate different rescue structure according to advantageous embodiments of the invention,

FIG. 21 illustrates a further applicable model of the modulator according to the invention,

FIGS. 22a and 22b illustrate an analog embodiment of the invention and where

FIG. 23 illustrates the filter characteristics of the embodiment of FIG. 22b and the resistors C1 and R8.

### DETAILED DESCRIPTION

Self-oscillating modulators have found some use over the recent years, but the use of such modulation techniques has up until now been restricted to relatively few market segments.

Examples of such self-oscillating modulators are WO 00/42702, WO 02/25357, WO 02/093973, U.S. Pat. No. 6,118,336, WO 98/19391, WO 00/27028, U.S. Pat. No. 6,249,182 hereby included by reference with respect to different basic principles regarding the establishment and controlling of the desired oscillation in combination with the desired modulation. It is noted that according to the invention it is generally preferred to apply a relatively high switch frequency in order to obtain not only the desired oscillation but also very powerful noise suppression obtained by the broad banded feedback path(s) of the self-oscillating modulator.

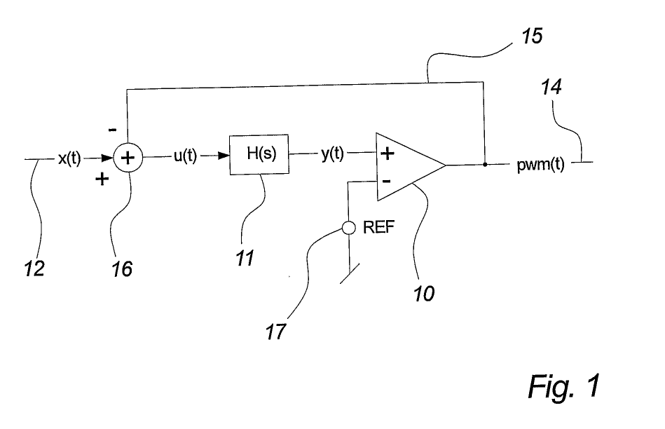

FIG. 1 illustrates an example of such a self-oscillating pulse width modulator.

From the beginning it should be noted that PWM in this context covers several different types of variations, such as NPWM, LPWM, etc. The illustrated PWM modulator utilizes in a known way the very broad banded feedback as error attenuation combined with the PWM modulation of the input signal. Evidently, according to the invention, several other self-oscillating topologies may be applied within the scope of the invention with further signal paths. Basically, the illustrated circuit should rather be regarded as a principle model of a self-oscillating modulator.

The illustrated self-oscillating modulator comprises an input 12 guiding an input signal x(t) to a non-linearity represented by a comparator 10 via a subtraction point 16 and compensating filtering means 11. Note that the non-linearity may be obtained and represented by alternative measures such as limiters, etc. The comparator 10 delivers an output pwm(t) on an output 14 of the circuit output. Moreover, this output is fed back to the subtraction point 16. The arranging of e.g. filtering means may be realized in several different ways, e.g. by inclusion of further filtering means e.g. in further (not shown) feedback or forward paths. Note that the illustrated embodiment features a comparator 10 having a variable voltage reference 17 instead of a fixed grounding in order to keep the switch frequency within a certain desired switch-frequency interval independent or substantially independent of the frequencies of the input signal. The variable voltage reference may be established in many ways within the scope of the invention, e.g. on the basis of the amplitude of the input signal of the modulator. An example of one principle applied for this purpose is known from WO 00/42702, hereby included by reference.

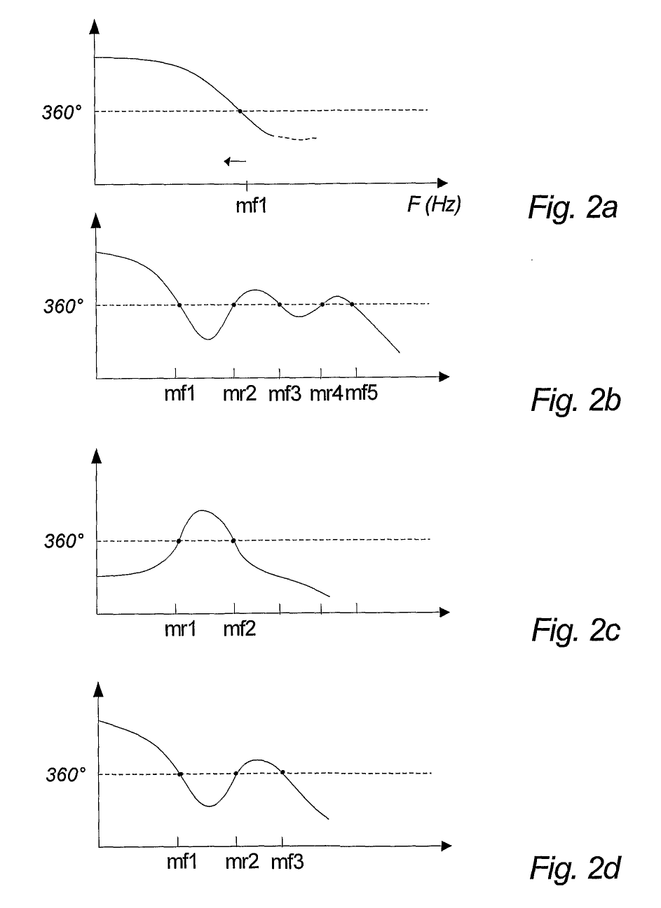

One way of looking at the modulator may be summed up: the open loop phase has to be approximately −360° at the desired switch frequency. The comparator will provide the gain. An example of a suitable filter H(s) may be illustrated in FIG. 2 where the switch frequency is approximately 384 kHz.

It is noted that the feed-back path and the forward path may be overlapping as the forward path in present embodiment refers to the patch between the input 12 and the output 14 and that the feedback patch 15 basically also includes the loop filter 11 which establishes the desired switching conditions in the present application.

FIG. 2A illustrates a phase response of a self-oscillating pulse modulator.

As previously described, a desired oscillation is conventionally reached when the open loop phase reaches 360° and the loop gain is unitary.

In this context is should be noted that open characteristics of the oscillator refers to the theoretical open loop characteristics during oscillation. Obviously, in practice, oscillation will only occur when the oscillation loop(s) is/are closed.

At the illustrated embodiment, a first mode mf1, invokes oscillation.

mfx designates the x'th mode, phase falling and mrx indicates the x'th mode, phase raising.

Initially, when looking at FIG. 2A is should be noted that the fundamental mode, the illustrated mode 1, if non-compensated, typically drifts during operation primarily as a function of modulator input amplitude.

Thus, the illustrated first mode, mf1, will tend to move to the left as illustrated towards lower frequencies when the input amplitude is increased.

Turning now to FIG. 2B, a characteristic of a multimode oscillating pulse modulator according to an embodiment of the invention is illustrated.

Again, oscillation at the fundamental mode ml may be reached. Oscillation may moreover be obtained at one of the further modes, e.g. mf3, i.e. a high-mode oscillation.

In other words, oscillation may, according to the invention be obtained in a high mode. In the illustrated embodiment oscillation is preferred in high falling modes, e.g. mf3 and mf5.

FIG. 2C illustrates a further embodiment of the invention, where a further embodiment of the invention involves an embodiment where a high-mode oscillation may be obtained in the second mode, mf2.

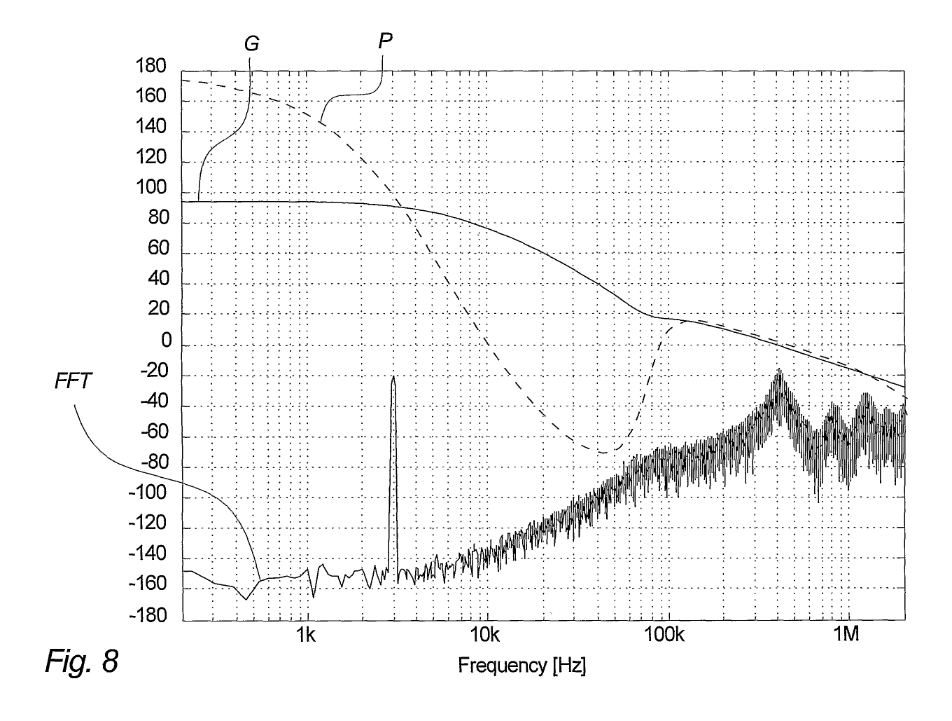

FIG. 2D illustrates a further schematic illustration corresponding to the illustrated embodiment of FIG. 8.

A more detailed explanation of some implementations of the above principles of different embodiments of the invention will be given below. Evidently, several other applications may be established according to the general principles of the present invention.

The modulator according to the invention may e.g. be applied in a context where the modulator is applied as an A/D converter and the signal must be sampled somewhere in the loop. The sampling may be obtained by a cheap 1 bit A/D converter simply consisting of or comprising a latch. This time quantization in the PWM signal can be directly compared to amplitude quantization in a PCM A/D converter, so the latch has to be clocked many times faster than the PWM switch rate. An advantageous property of the system is that the loop errors are attenuated by the loop gain—including this quantization noise.

Referring now to an important aspect of the above illustrated embodiments of the invention a further feature of important high-mode self-oscillating principles will be explained and outlined.

This design feature of a high-mode oscillator will result in extremely advantageous performance if applied as below described. In order to obtain the desired advantageous performance, a high-mode margin must be identified and design carefully. According to the terms of the invention, the high mode margin refers to the difference in frequency between the high mode in which the oscillator switches and the previous mode.

Thus, if the example of FIG. 2c is intended to switch in mode mf2, the high-mode margin is given by high-mode margin=mf2−mr1.

It has been established that a major benefit of the invention obtained when the high-mode margin is less than 150 kHz at a high mode switch frequency of e.g. 200 kHz.

Generally it has been established that the high-mode margin should be less than 75% of the switch frequency of the high mode.

It has also been established according to the invention that such high-mode margin may be obtained relatively simple by keeping the maximum change of open loop phase between the high-mode switching mode and the previous mode as explained above must be less than about 90°. This designation of phase shift refers to the difference in phase between the high mode/previous mode (at 360° crossing) and the “mountain-top” phase of FIG. 2c.

In an analog implementation of the invention this phase shift should be less than 90° but preferably as low as about 50°. In a preferred analog embodiment of the invention this phase shift should be about 30°.

In a digital implementation this phase shift should preferably be less than 30°.

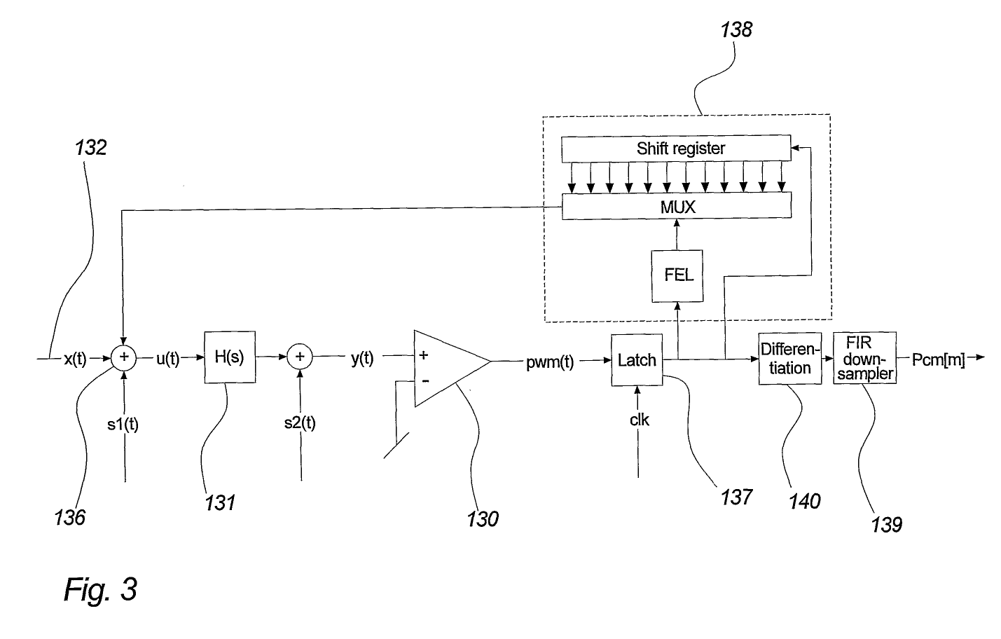

FIG. 3 illustrates an example of such an A/D converter, according to an embodiment of the invention. The illustrated converter comprises an input 132, which via a subtracting point 136 and filtering means 131 is fed to a comparator 130. The output of the comparator 130 is fed to a latch 137, which again outputs a time-quantized signal via a differentiator 140 to a down sampling circuit 139 outputting a PCM down sampled signal. The output of the latch is furthermore fed back and added to the input 132.

The feedback path comprises a frequency control 138 for fixation of switch frequency or at least for obtaining a steady switch frequency. When the switch frequency is allowed to fluctuate it may cause interference problems when, e.g. several self-oscillating A/D-converters are implemented on a single printed circuit board, or close to each other. Furthermore a stable switch frequency facilitates synchronization of several converters. It comprises a frequency estimator FEL, a multiplexer MUX and a shift register. The shift register receives the output values from the latch, e.g. as in a first-in-first-out FIFO register, and thus retains information about an appropriate number of these values. The specific number of values that should be remembered depends on the particular embodiment, and may correspond to, e.g. the number of values established by the latch within a fraction of a switch period, in principle within ½ of a period of the desired switch frequency and more practically usable within, e.g. 1/10 of a period of the desired switch frequency. For each latch output value, the oldest value in the shift register is discarded. The frequency estimator FEL monitors the switch frequency by monitoring the output of the latch, and controls, by means of the multiplexer MUX, which of the retained output values that should be fed back to the input 132. The frequency control 138 is thereby able to vary the loop delay, i.e. the time by which the output values are delayed before fed back to the input 132, which again results in a variation of the switch frequency. The self-oscillation switch frequency in this embodiment is thus basically determined by the filtering means 131 in combination with the frequency control 138. This design is basically applied for the purpose of counteracting the influence of variations of the input amplitude on the switch frequency.

It is noted that the specific embodiment of a frequency control shown in FIG. 3 may be substituted by any possible means for controlling the loop delay, or variants of the embodiment of FIG. 3. Furthermore, the frequency control, i.e. a variable loop delay, may be positioned in the signal forward path instead of, or in addition to, in the feedback path.

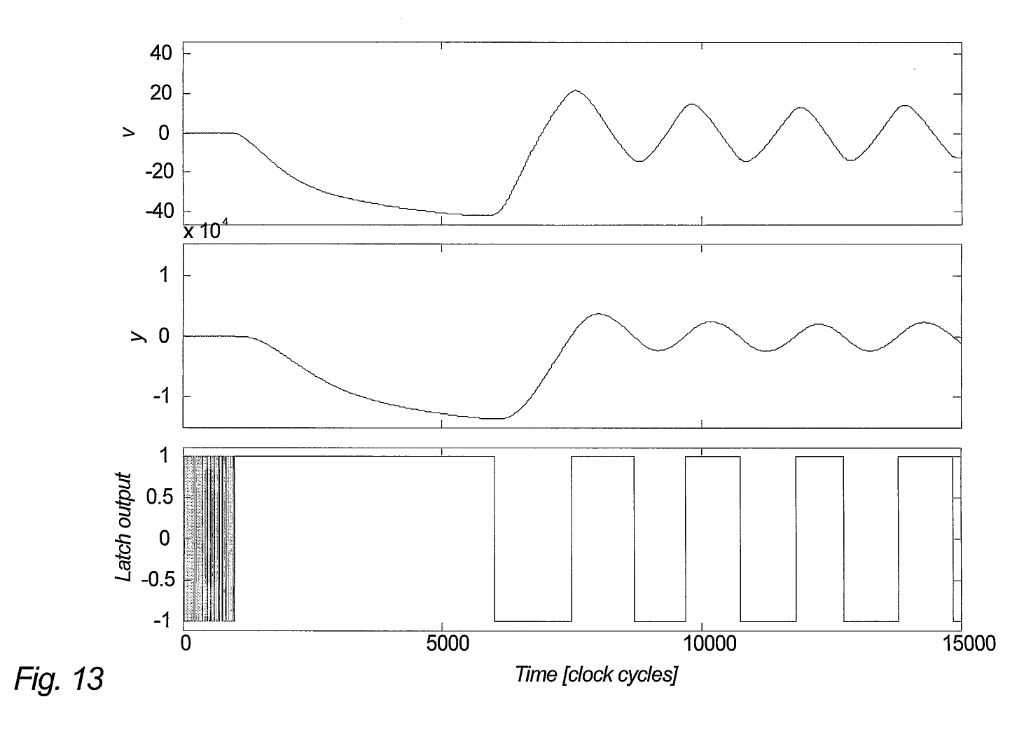

FIG. 3 further comprises additional inputs s1(t) and s2(t). These may also be used for controlling or influencing the switch frequency. By applying to one of these inputs a periodic signal or a harmonic related thereto, preferably a square wave but any waveform type or composite type may be used, having a frequency equal to the desired switch frequency, this periodic signal is added to the input signal x(t) or filtered input signal y(t). This again causes the switch frequency of the self-oscillating loop to substantially stick to the frequency of the additional input signal s1(t) or s2(t). The additional signal may have an amplitude of, e.g. 5% of the maximum input signal amplitude. Preferably only one additional input should be used, but FIG. 13 shows different preferred positions to apply this input. It should be noted that applying the additional periodic signal anywhere else in the circuit is, however, within the scope of the present invention not preferred.

When both the variable loop delay, e.g. controlled by the frequency control 138, and the additional periodic signal s1(t) or s2(t) are applied in one embodiment, the primary purpose of the variable loop delay is to maintain the switch frequency within a tolerance, i.e. roughly locking the frequency, whereas the primary purpose of the additional periodic signal is to restrict this tolerance further, i.e. preferably completely lock the switch frequency.

The above-explained A/D-converter benefits from a fixed and “lockable” switch rate. A fixed switch rate will make the system more immune to neighboring channels, and will make the down sample task easier.

As mentioned earlier, the oscillation frequency is determined on the basis of the open loop phase response. This phase response also incorporates the delay in the comparator and the spread in analog components parameters, so the exact switch frequency may be difficult to predict unless measures for locking switching frequency is applied. This feature is both relevant with respect to the analog and digital implementation. Furthermore, the oscillator circuit itself will reduce the switch frequency for high-level input signals.

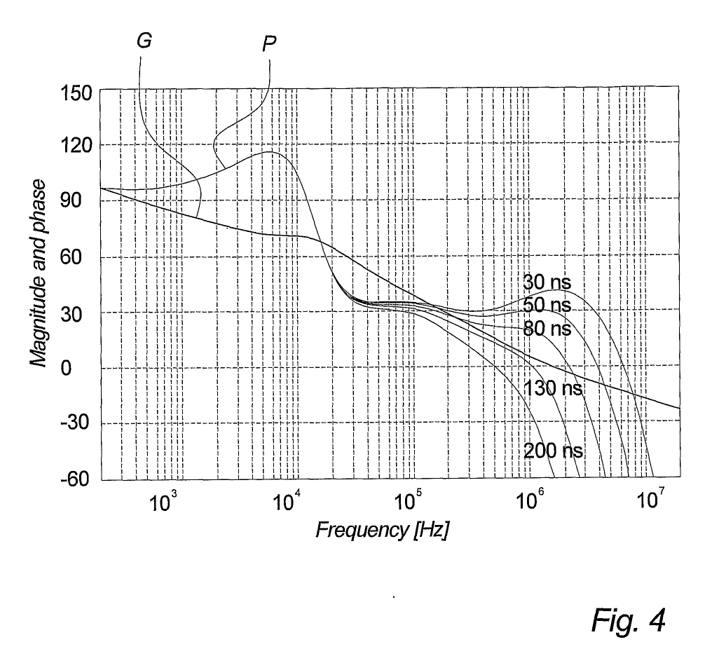

An adaptive adjustment of the loop phase response of the above explained types enables switch frequency corrections as the switch frequency is monitored, and as a function of the switch frequency, the delay (phase) is adjusted. If the switch frequency is too high, the delay is increased, thus moving the −180° cross point to the left. If the switch frequency is too low, the delay is decreased, thus moving the −180° cross point to the right. An example of the delay change consequence is illustrated for explanatory purposes in FIG. 4 where phase response P and open loop gain G is illustrated as a function of the digital delay, i.e. the settings of the MUX 138 settings.

Although this frequency adjustment is only made with certain accuracy limited by the time resolution and therefore only offers a “coarse” adjustment, a small synchronization signal with the desired switch frequency will tend to “lock” the free-running oscillator.

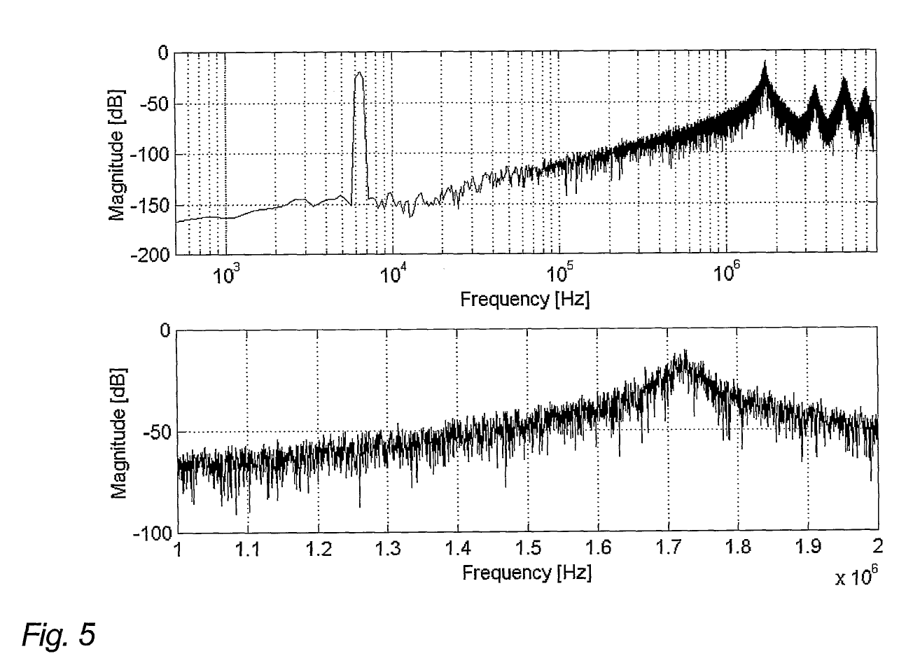

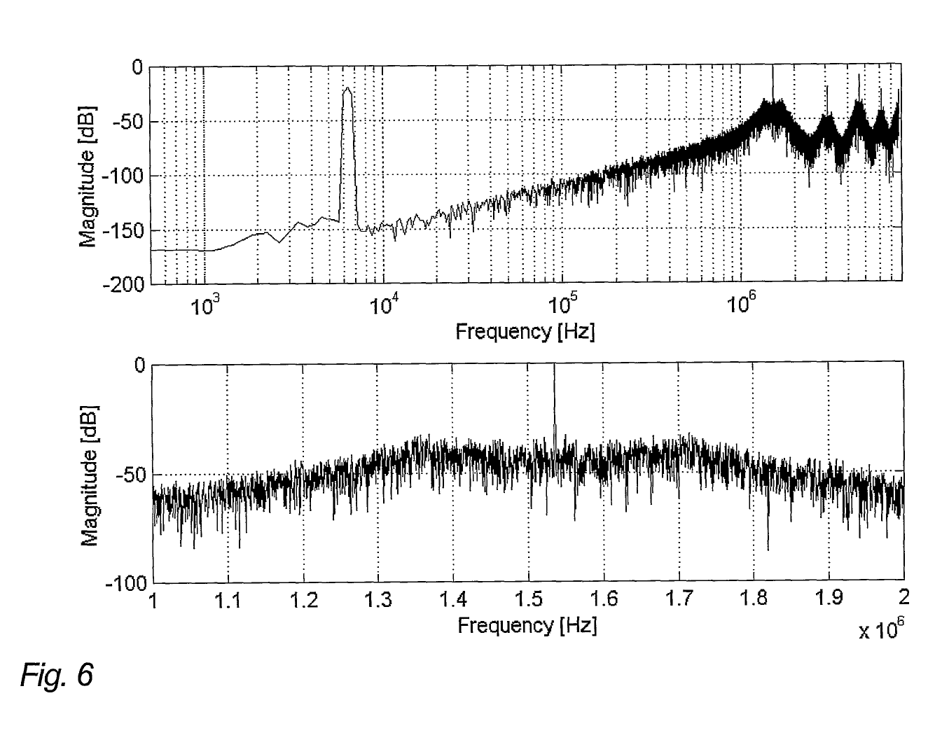

An example of the lock effect in the frequency domain is shown in FIG. 5 and FIG. 6, the input signal, x(t), is a 6.4 KHz-20 dB sinusoidal and the synchronization signal, s1(t) in FIG. 3 is a −26 dB 1.536 MHz square wave. In other words, FIG. 5 illustrates a PWM output spectrum of FIG. 3 without synchronization signal and FIG. 6 illustrates a PWM output spectrum of FIG. 3 when a synchronization signal is applied.

It should be noted that the frequency control means 138 are optional although very advantageous. Moreover, frequency control or synchronization may be obtained in several other ways than the above illustrated.

It should moreover be noted that the desired high-mode oscillation may be obtained by a suitable filter design of conventional self-oscillating modulators. Thus, the above-illustrated self-oscillating hardware structure of FIG. 3 may be designed to operate in both fundamental modes—as a conventional self-oscillating modulator—and in high mode—according to the present invention.

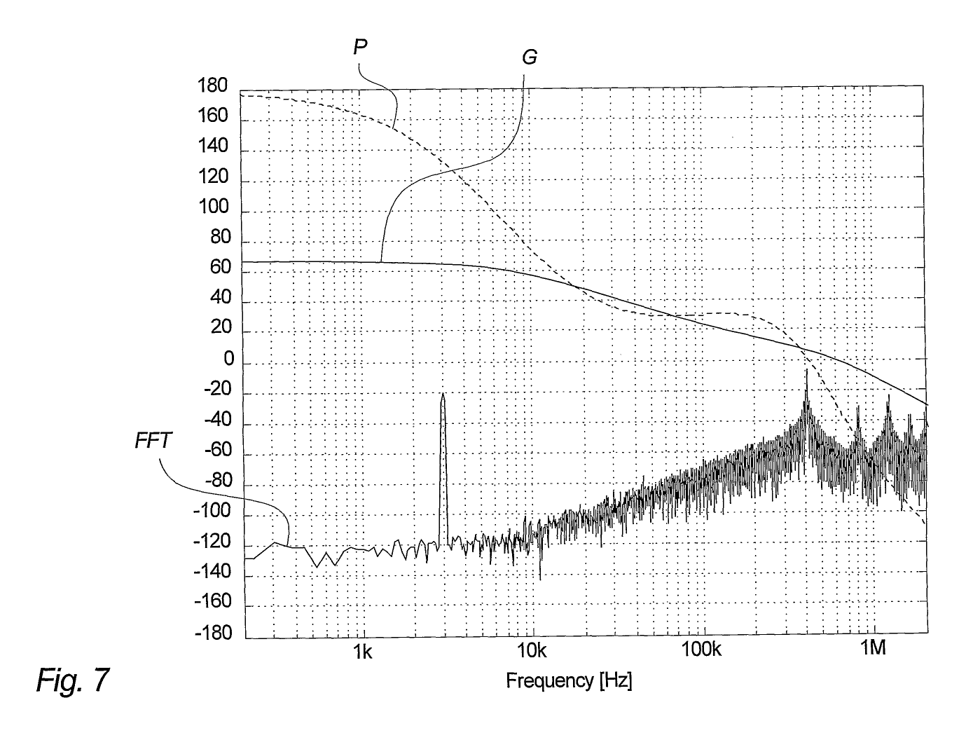

A loop filter in a self-oscillating modulator may generally be designed in many ways. A general rule of thumb is to have some phase margin until the desired switch frequency is reached. An example of such a design is shown in FIG. 7 illustrated by open loop gain G and open loop phase P. The illustrated loop filter in this example consists of:

1 simple pole at 5 kHz
1 simple pole at 10 kHz
1 simple zero at 130 kHz
1 complex pole at 550 kHz, Q=0.75

The FFT result shown in FIG. 7 is the FFT of the latch output found in FIG. 3. In this case the MUX has been bypassed, so no extra delay is introduced in the feedback. The clock rate in the simulations in this chapter is 20 MHz (50 ns). With a PWM switch frequency at 400 kHz (2.5 us), that is equivalent to a time resolution of log 2(2.5e−6/50e−9)=5.64 bit.

The conventional single-mode crossing corresponds to the design principles of FIG. 1B has some limitations in the slope of error-suppression.

Turning now to a high-mode self-oscillating pulse modulator according to an embodiment of the invention

The following FIG. 8 to 16 show loop filter characteristics and illustrate that it is not only possible to apply high modes of the self-oscillating modulator, according to the invention, but also that it may be possible to switch between different modes. This mode control may be applied for different purposes. Gain is designated in the figures by G and phase by P.

The feature, that a self oscillating modulator is able to actively and under control change between at least two different modes may, enable the modulator to operate e.g. in a fundamental first mode as conventional oscillating modulators, LO-mode and change into a higher mode when higher quality is desired or required.

Thus a multimode PWM may enable an oscillation in different selectable modes which may actively, typically automatically according to predefined algorithms, be selected e.g. to minimize the energy consumption under certain conditions and optimize the PWM quality under other conditions.

A high-mode self-oscillating pulse modulator may be obtained by increasing the filter order so the phase-margin drops below zero degree, enables the possibility to have an even steeper slope of the error-suppression curve. An example of such design is shown in FIG. 8. The illustrated high-mode modulator has three modes, thus enabling more than one “operating frequency”. The illustrated embodiment oscillates in the third mode mf3 at falling phase. The third mode enables oscillation at 400 kHz, i.e. a high “oscillating mode”.

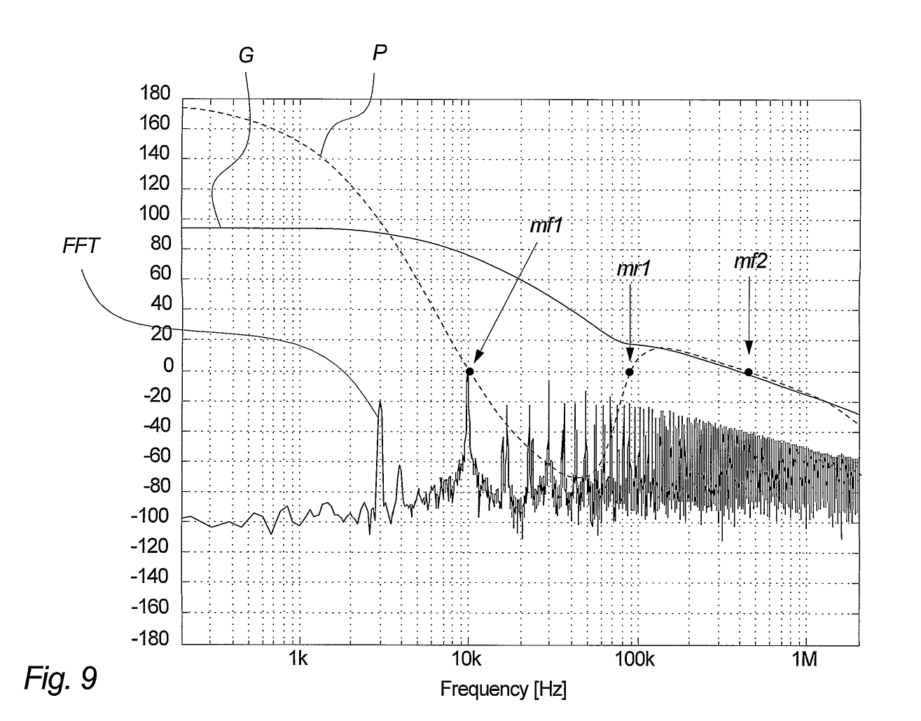

Using the same algorithm, the PWM modulator can be brought into the “low oscillating mode” mf1 by for example forcing the PWM output—which is fed back to the input—to a fixed state in a couple of hundred micro seconds corresponding to about 5000 clock cycles. When the PWM operates in this mode, the switch frequency is located at the fundamental model mf1 which is located at approx. 10 kHz. It is noted that error-suppression effect in this mode is reduced and the effective 0 dB loop-gain frequency-point has been moved from 400 kHz to 10 kHz. The effect can be seen in FIG. 9.

The results in FIG. 8 and FIG. 9 have been obtained using a time discrete loop filter having:

3 simple poles at 6 kHz
1 complex zero at 75 kHz, Q=2
1 simple pole at 85 kHz

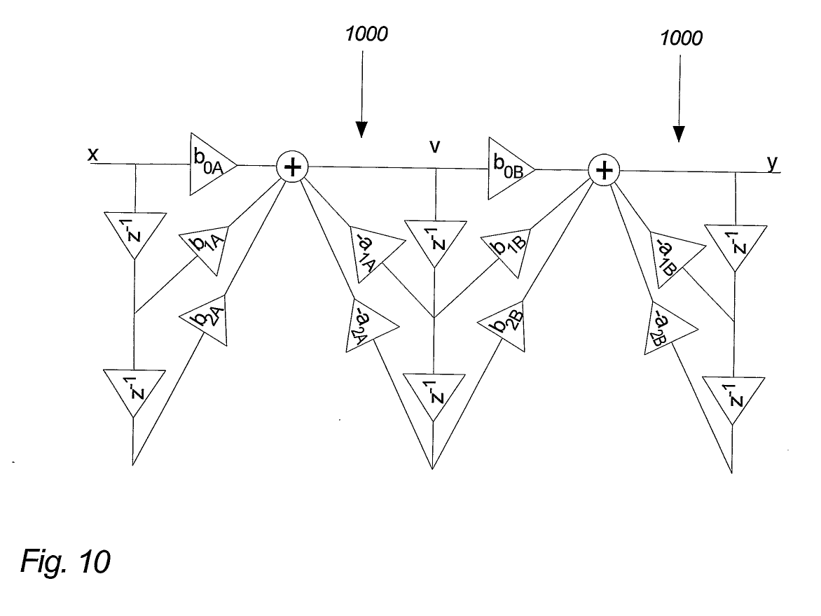

The filter is implemented as two cascaded second order IIR sections 1000 as shown in FIG. 10. The input x is prescaled with 0.25, so that the filter state values in normal operation is inside the range −1 to +1.

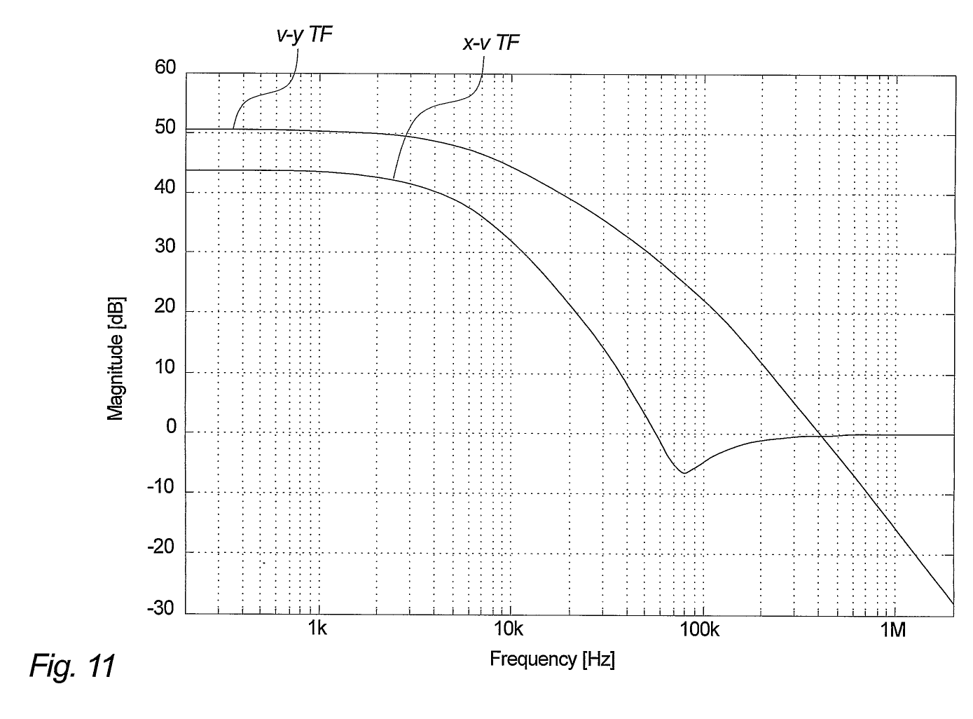

The second-order sectioning approach is used to reduce component/coefficient sensitivity and to reduce the output noise as a function of internal noise sources such as resistors, transistors and quantization. In this case the 4^{th} order filter has been parted in the two transfer functions shown in FIG. 11.

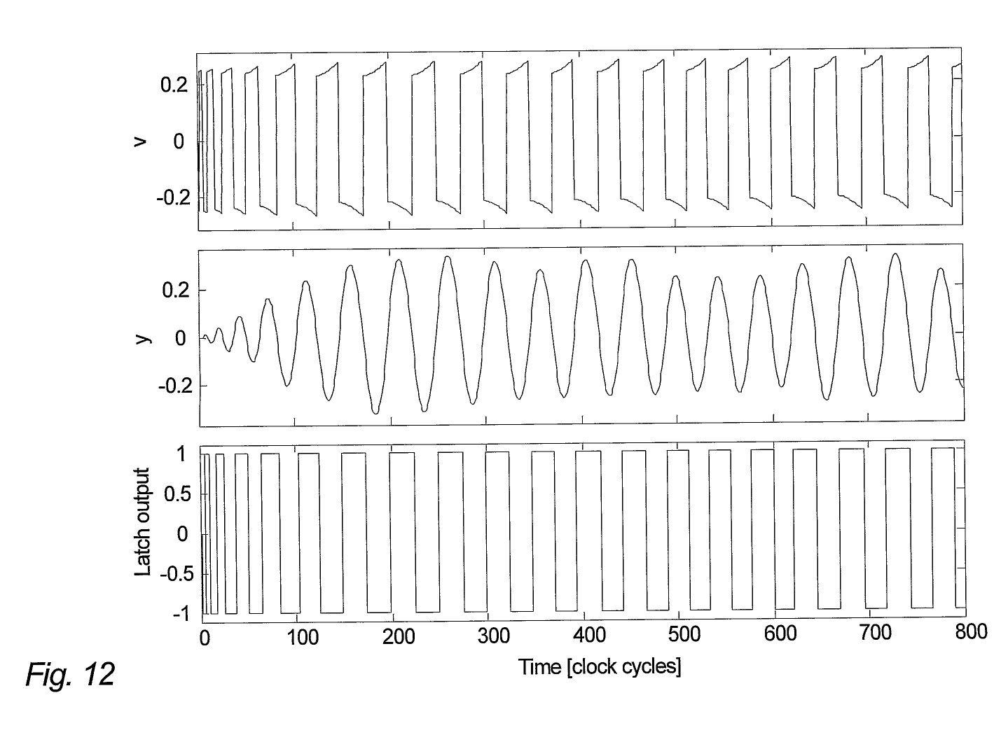

FIG. 12 illustrates a normal start-up applied when targeting the “HI-mode”.

In a normal start-up situation, the modulator will enter the “HI-mode” as shown in FIG. 12, where the PWM period time is close to 50 clock cycles corresponding to 400 kHz.

A way of switching between the high mode and the low mode is explained below. The switching may be obtained by forcing the output latch of the modulator to a fixed state in a long period, i.e. a longer period than the desired rate. Initially, the modulator will oscillate in the high mode, i.e. for the first 1000 clock cycles. After that period the output is forced to +1 for the following 5000 clock cycles. After these 5000 cycles the output is released and it can be observed that the modulator will enter the LO mode at about 10 kHz.

The filter gain for both IIR sections 1000—biquads at this low frequency are rather high (>30 dB), so the filter output signals have high amplitude, especially at the last stage where the signal is boosted by 80 dB.

One way of disabling these unwanted low-frequency and high-amplitude oscillations is simply to introduce non-linear elements in the loop, which only have an effect when the system tries to enter LO modes.

An example could be to introduce limiters 1400 in the loop filter as shown in FIG. 14. These limiters 1400 will reduce or remove the possibility of unwanted low-frequency and high-amplitude oscillations.

It should be noted that this limiting strategy easily may be implemented in an analog version as well. Thus, such limitation may often occur automatically due to limited supply voltage of the applied filter circuit.

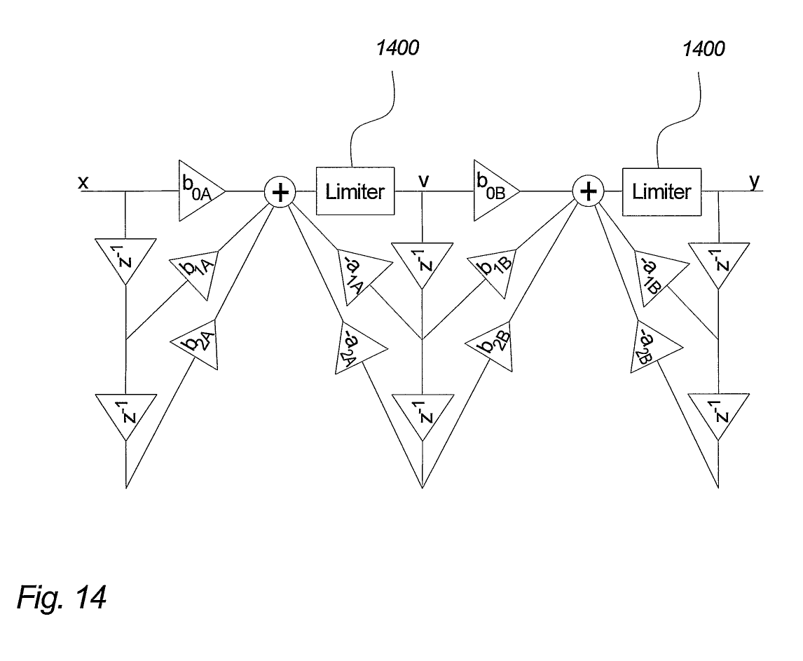

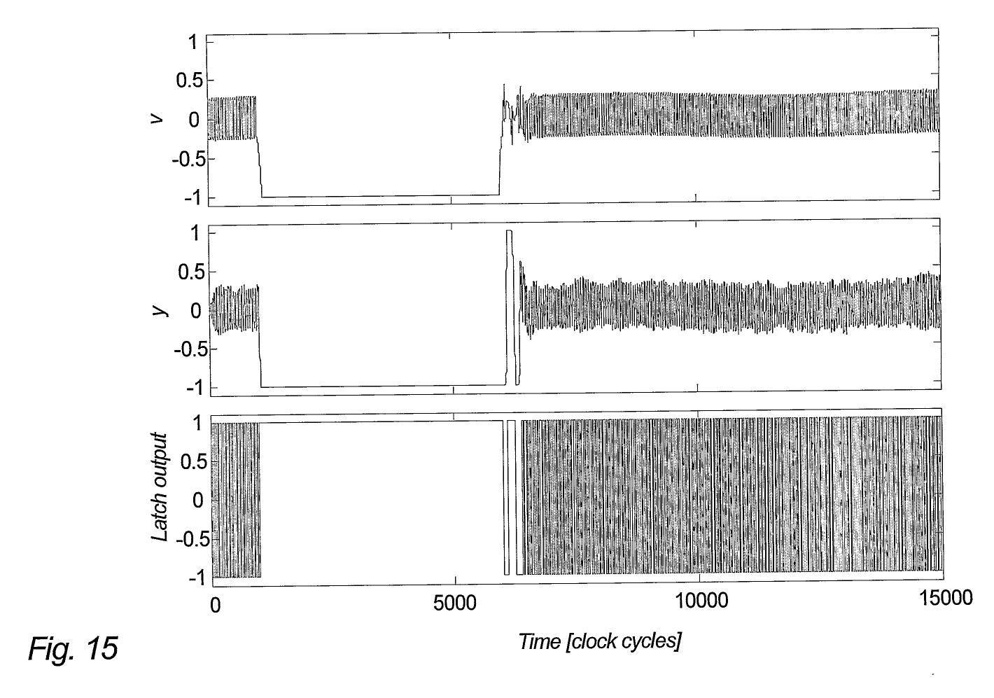

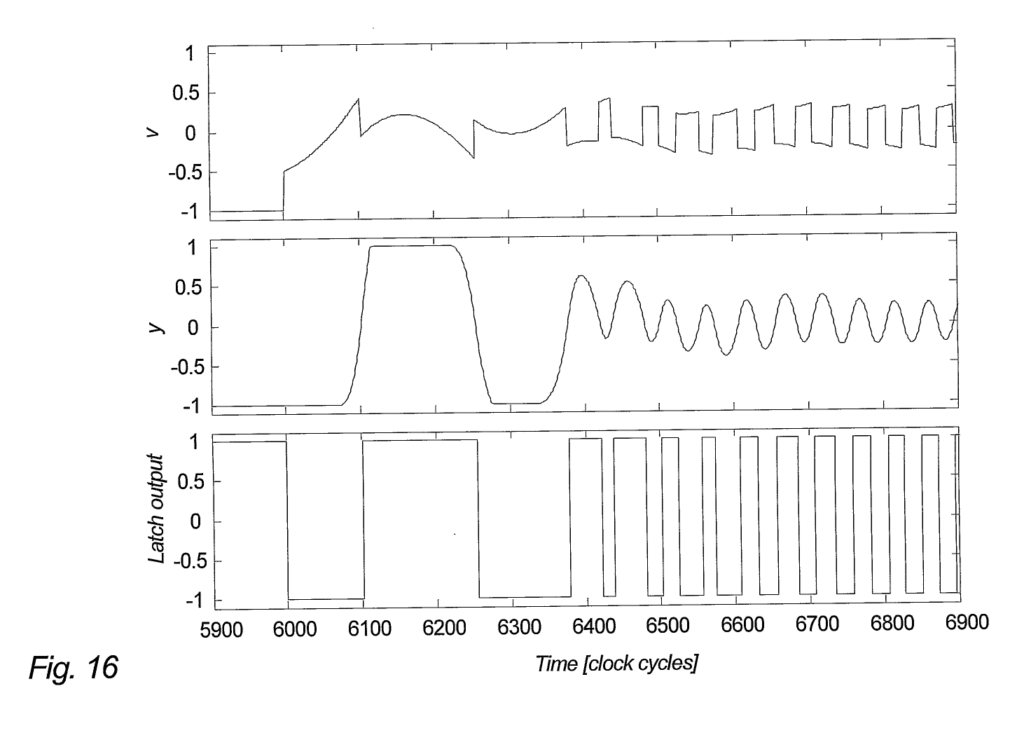

The result of applying limiters inside the filters when applying the same setup as in FIG. 13 the switching is illustrated in FIG. 15 and FIG. 16.

Thus, after the “force period”, it is noted that the output signal y signal is limited to first +1 and then −1. After these events, the modulator returns to the preferred HI mode.

FIG. 16 illustrates a zoomed returning to the HI-mode.

A feature of a further advantageous embodiment of the invention implies the application of a rescue mechanism. Evidently, as it will be understood, the term rescue mechanism refers to an electrical rather than a mechanical circuitry and that the term rescue merely refers to a circuitry applied for the purpose bringing the oscillating modulator into the desired switch condition.

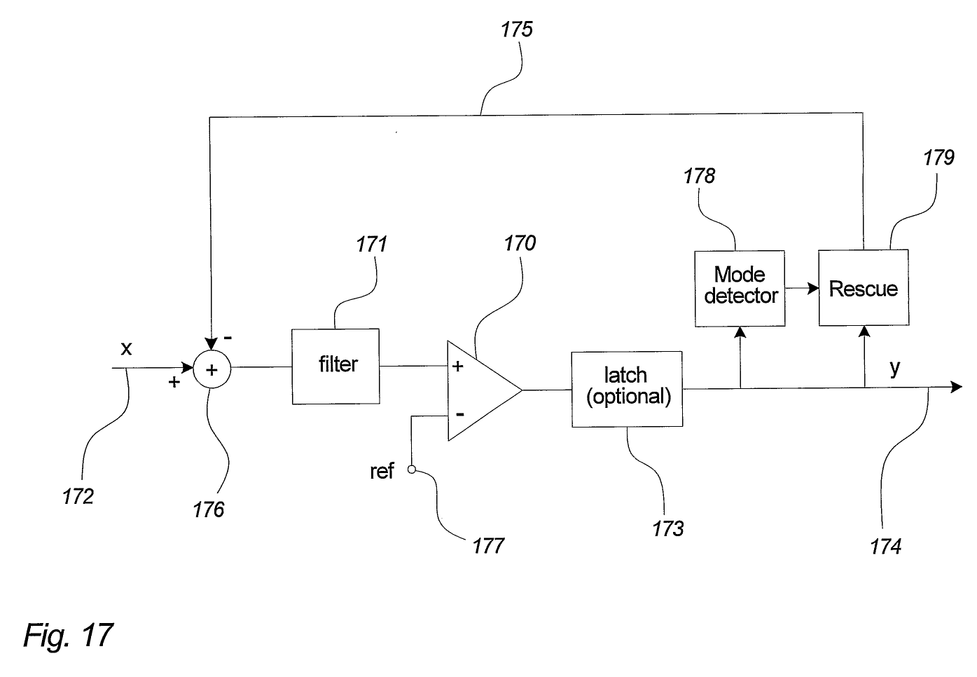

FIG. 17 illustrates a first embodiment of such rescue mechanism.

The illustrated self-oscillating modulator comprises an input 172 guiding an input signal x(t) to a non-linearity 170 via a subtraction point 176 and filtering means 171. Note that the non-linearity may be obtained and represented by alternative measures such as comparators, limiters, etc. The non-linearity 170 delivers an output pwm(t) on an output 174 of the circuit output. Moreover, this output is fed back to the subtraction point 176 via a rescue block 179 controlled by a mode detector 178. The arranging of e.g. filtering means may be realized in several different ways, e.g. by inclusion of further filtering means e.g. in further (not shown) feedback or forward paths. A latch 173 on the output of the non-linearity 170 is optional.

The mode detector 178 monitors unwanted modes. The mode detector may e.g. simply be implemented as a counter that monitors the duration of a PWM pulse; here the length of a “+1 state” or length of a “−1 state”. If the length exceeds the expected length of a PWM pulse running in the desired mode, the mode detector 178 signals to the rescue block 179. The rescue block 179 may simply disconnect, tri-state, the feedback in a given time period, thus suppressing the unwanted mode.

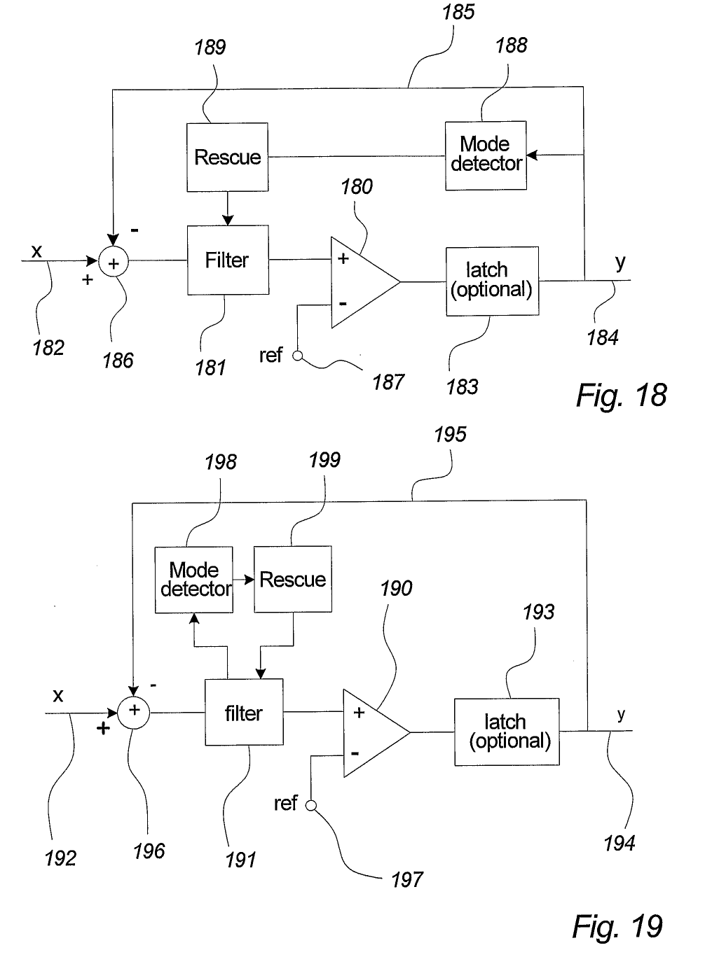

FIG. 18 illustrates a second embodiment of a rescue mechanism in a high-mode self-oscillating modulator, according to a further advantageous embodiment of the invention.

The illustrated self-oscillating modulator comprises an input 182 guiding an input signal x(t) to a non-linearity 180 via a subtraction point 186 and compensating filtering means 181. Note that the non-linearity may be obtained and represented by alternative measures such as comparators, limiters, etc. The non-linearity 180 delivers an output pwm(t) on an output 184 of the circuit output. Moreover, this output is fed back to the subtraction point 186.

A rescue block 189 is moreover controlled by a mode detector 188. The arranging of e.g. filtering means may be realized in several different ways, e.g. by inclusion of further filtering means e.g. in further (not shown) feedback or forward paths. A latch 183 on the output of the non-linearity 180 is optional.

The mode detector 188 monitors unwanted modes. The mode detector 188 may e.g. simply be implemented as a counter that monitors the duration of a PWM pulse; here the length of a “+1 state” or length of a “−1 state”. If the length exceeds the expected length of a PWM pulse running in the desired mode, the mode detector 188 signals to the rescue block 189. The rescue block 189 may obtain the desired mode-cancellation by e.g. resetting, discharging or limiting the filtering means 181.

FIG. 19 illustrates a third embodiment of a rescue mechanism in a high-mode self-oscillating modulator according to a further advantageous embodiment of the invention.

The illustrated self-oscillating modulator comprises an input 192 guiding an input signal x(t) to a non-linearity 190 via a subtraction point 196 and filtering means 191. Note that the non-linearity may be obtained and represented by alternative measures such as comparators, limiters, etc. The non-linearity 190 delivers an output pwm(t) on an output 194 of the circuit output. Moreover, this output is fed back to the subtraction point 196.

A rescue block 199 is moreover controlled by a mode detector 198. The arranging of e.g. filtering means may be realized in several different ways, e.g. by inclusion of further filtering means e.g. in further (not shown) feedback or forward paths. A latch 193 on the output of the non-linearity 190 is optional.

The mode detector 198 monitors' unwanted modes directly in the filtering means 191 and the mode detector 198 signals to the rescue block 199 if undesired mode(s) are present. The rescue block 199 may obtain the desired mode-cancellation by e.g. resetting, discharging or limiting the filtering means 191.

One way of detecting an undesired mode is to monitor the amplitude of the filter states. If the modulator enters a LO mode, the amplitude rises and the detector 198 can then send out a control signal to the rescue block 199 which can reset, discharge or limit filter stage. In both of the above implementations, the mode detector as well as the rescue block are implicit in the filter-limiting operation.

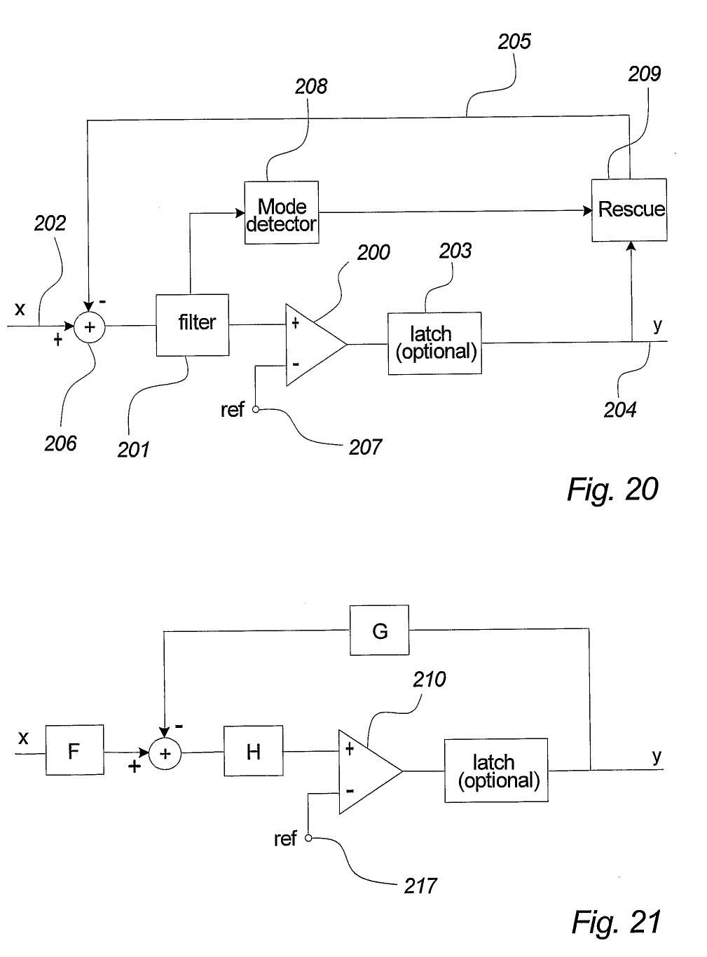

FIG. 20 illustrates a further embodiment of the implementation of a rescue mechanism.

The illustrated self-oscillating modulator comprises an input 202 guiding an input signal x(t) to a non-linearity 200 via a subtraction point 206 and filtering means 201. Note that the non-linearity may be obtained and represented by alternative measures such as comparators, limiters, etc. The non-linearity 200 delivers an output pwm(t) on an output 204 of the circuit output. Moreover, this output is fed back to the subtraction point 206 via a rescue block 209 controlled by a mode detector 208. The arranging of e.g. filtering means may be realized in several different ways, e.g. by inclusion of further filtering means e.g. in further (not shown) feedback or forward paths. A latch 203 on the output of the non-linearity 200 is optional.

The mode detector 208 monitors unwanted modes directly in the filtering means 201 and controls the rescue block 209 accordingly. The rescue block 209 may simply disconnect, tri-state, the feedback in a given period of time, thus suppressing the unwanted mode.

In this example the mode detector monitors the filter states, or at least some of them. One way of detecting an undesired mode is to monitor the amplitude of the filter states. If the modulator enters a LO mode, the amplitude rises and the detector can then send out a control signal to the rescue block which can disconnect the feedback as FIG. 17.

### Loop Filter Structure

All discussions in this document are based on the modulator model shown in FIG. 1A.

In especially an analog implementation, different physical limitations must be considered, like slew-rate in an op-amp. Often the signal has to be band-limited before it reaches an active element like an op-amp, so the filter structure can be changed to another applicable model as illustrated in FIG. 21.

The illustrated model of a self-oscillating modulator, according to the invention, comprises an input guiding an input signal x(t) to a non-linearity 210 via a block F, a subtraction point and a block H. The non-linearity delivers an output y on an output. Moreover, this output is fed back to the subtraction point via a block G. The non-linearity may moreover be connected to a reference 217. Again, the variable voltage reference 217 may be established in many ways within the scope of the invention, e.g. on the basis of the amplitude of the input signal of the modulator. An example of one principle applied for this purpose is known from WO 00/42702, hereby included by reference.

### This Model

When the non-linearity 210 is regarded as a linear gain k the transfer function can be found as:

$$Y = X \cdot F \cdot H \cdot k - Y \cdot G \cdot H \cdot k \\ ⇕ \\ Y ( 1 + G \cdot H \cdot k ) = X \cdot F \cdot H \cdot k \\ ⇕ \\ \frac{Y}{X} = \frac{F \cdot H \cdot k}{1 + G \cdot H \cdot k} \\$$

Seen from a stability and error suppression point of view, only G and H are interesting. The output as a function of injected quantization noise, Q, is:

$$Y = Q - Y \cdot G \cdot H \cdot k \\ ⇕ \\ Y ( 1 + G \cdot H \cdot k ) = Q \\ ⇕ \\ \frac{Y}{Q} = \frac{1}{1 + G \cdot H \cdot k}$$

The transfer function F only affects the input to output relation.

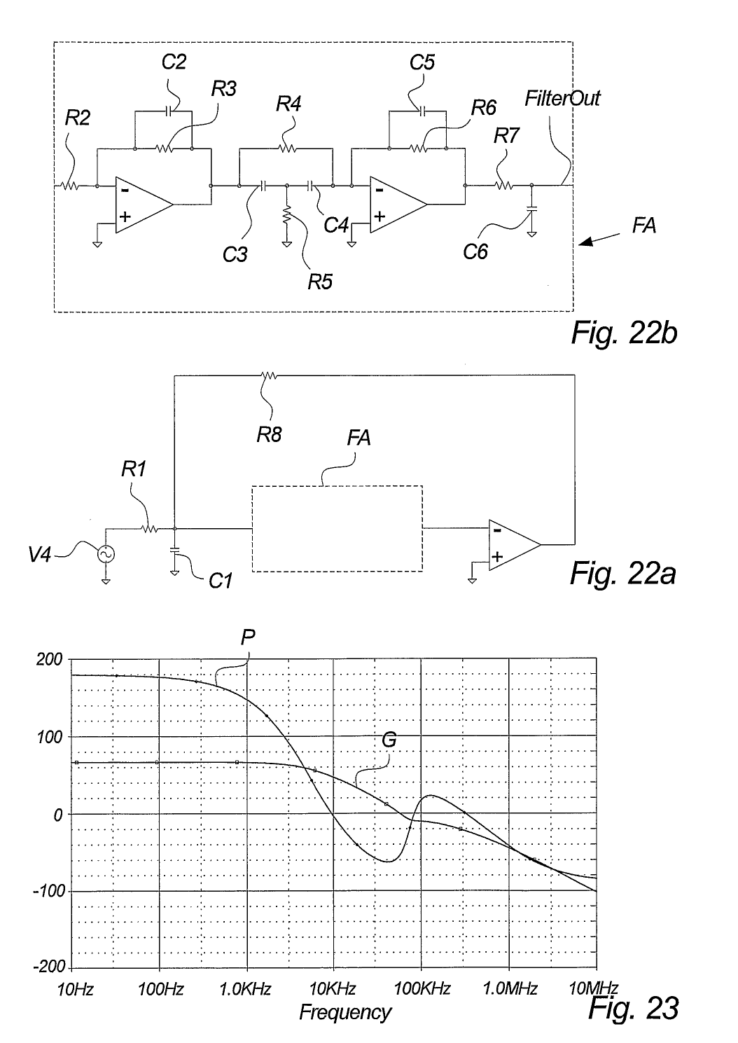

FIGS. 22a and 22b illustrate a further advantageous embodiment of the invention now in an analog implementation.

FIG. 22a illustrates the principle components of an analog implemented PWM modulator and FIG. 22b illustrates an example of a specific filter arrangement of the PWM modulator of FIG. 22a.

The illustrated embodiment, representing just one of several applicable analog representations, comprises and input represented by a voltage generator V4 connected to a loop filtering arrangement FA via a resistor R1 and grounded by a capacitor. The filtering arrangement FA is connected to the inverted input of a non-linearity NL, here comprised by a comparator.

The output of the comparator constitutes the output of the PWM.

The output is fed back to the input of the filtering arrangement FA via a resistor R8.

R8 and R1 are 10 k and C1 is 15 n.

Turning now to FIG. 22b, illustrated a specific topology of a filtering arrangement FA of FIG. 22a, the input is basically based on two serially coupled comparators 220 and 221 forming or forming part of a low-pass filtering circuit.

The components forming the low-pass filtering arrangement FA are listed below

R2 is 4 k7, R3 is 5600 k, R4 is 10 k, R5 is 680, R6 is 56 k, R7 and 1.8 k (ohms).
C2 is 4 p7, C3 and C4 are 820 p, C5 is 470 p and C6 is 100 p (farad).

FIG. 23 illustrates the resulting characteristics of the above-disclosed PWM filter arrangement of FIG. 22b including the resistor R8 and the capacitor C1, where G illustrates the amplitude and P designates the open loop phase characteristic of the above circuit. It is noted that the illustrated analog embodiment in many ways corresponds to the digital implementation of FIG. 8.

Applications of the above-explained pulse modulator includes high and low power PWM, A/D and D/A converters, power stage control, power supplies, etc.

1.-34. (canceled)

35. High-mode self-oscillating pulse modulator
wherein the oscillating pulse modulator comprises an input, an output, at least one forward path and at least one feedback path,
said at least one forward path comprising at least one non-linearity,
said at least one feedback path comprising a loop-filter arrangement
said oscillating modulator having a switching frequency which is established on the basis of oscillation in said at least non-linearity and said loop-filter arrangement,
wherein said switching frequency is established at the second or higher zero crossing of the phase margin of the open loop filter.

36. High-mode self-oscillating pulse modulator, wherein the oscillating pulse modulator comprises an input, an output, at least one forward path and at least one feedback path,
said at least one forward path comprising at least one non-linearity,
said at least one feedback path comprising a loop-filter arrangement,
said modulator further comprising a lock signal generator or a lock signal input,
said oscillating modulator having a switching frequency which is established on the basis of oscillation in said at least non-linearity and said loop-filter arrangement combined with a lock signal generated by said lock signal generator or a lock signal input.

37. High-mode self-oscillating pulse modulator according to claim 35, wherein said oscillating modulator is a pulse width modulator.

38. High-mode self-oscillating pulse modulator according to claim 35, wherein said pulse width modulator is a mode two or mode three oscillator.

39. High-mode self-oscillating pulse modulator according to claim 35, wherein the high mode margin is less than 800 kHz, preferably less than 500 kHz and most preferably less than 400 kHz.

40. High-mode self-oscillating pulse modulator according to claim 35, wherein the high mode margin is less than 75% of the switch frequency at a switching frequency of at least 10 kHz.

41. High-mode self-oscillating pulse modulator according to claim 35, wherein the high mode margin is less than 75% of the switch frequency at a switching frequency of at least 200 kHz.

42. High-mode self-oscillating pulse modulator according to claim 35, wherein said loop filter has a negative phase margin.

43. High-mode self-oscillating pulse modulator according to any of the claim 35, wherein said loop filter has a negative phase margin.

44. High-mode self-oscillating pulse modulator according to claim 35, wherein said pulse modulator is a multimode modulator.

45. High-mode self-oscillating pulse modulator according to claim 35, wherein said non-linearity comprises a limiter or a comparator.

46. High-mode self-oscillating pulse modulator according to claim 35, wherein said loop-filter arrangement comprises a loop filter and that the effective order of said loop filter is greater than two below switching frequency.

47. High-mode self-oscillating pulse modulator according to claim 35, wherein the effective order of said loop filter is three.

48. High-mode self-oscillating pulse modulator according to claim 35, wherein said self-oscillating pulse modulator comprises rescue means and mode detecting means and wherein said rescue means suppresses or cancels unwanted modes detected by said mode detecting means.

49. High-mode self-oscillating pulse modulator according to claim 35, wherein said modulator forms part of a multi-channel modulator circuitry and wherein the switching frequency of the modulators are synchronized, either in a mutual synchronization or in relation to a common switching frequency reference.

50. High-mode self-oscillating pulse modulator according to claim 36, wherein said oscillating modulator is a pulse width modulator.

51. High-mode self-oscillating pulse modulator according to claim 36, wherein said pulse width modulator is a mode two or mode three oscillator.

52. High-mode self-oscillating pulse modulator according to claim 36, wherein the high mode margin is less than 800 kHz, preferably less than 500 kHz and most preferably less than 400 kHz.

53. High-mode self-oscillating pulse modulator according to claim 36, wherein the high mode margin is less than 75% of the switch frequency at a switching frequency of at least 10 kHz.

54. High-mode self-oscillating pulse modulator according to claim 36, wherein the high mode margin is less than 75% of the switch frequency at a switching frequency of at least 200 kHz.

55. High-mode self-oscillating pulse modulator according to claim 36, wherein said loop filter has a negative phase margin.

56. High-mode self-oscillating pulse modulator according to any of the claim 36, wherein said loop filter has a negative phase margin.

57. High-mode self-oscillating pulse modulator according to claim 36, wherein said pulse modulator is a multimode modulator.

58. High-mode self-oscillating pulse modulator according to claim 36, wherein said non-linearity comprises a limiter or a comparator.

59. High-mode self-oscillating pulse modulator according to claim 36, wherein said loop-filter arrangement comprises a loop filter and that the effective order of said loop filter is greater than two below switching frequency.

60. High-mode self-oscillating pulse modulator according to claim 36, wherein the effective order of said loop filter is three.

61. High-mode self-oscillating pulse modulator according to claim 36, wherein said self-oscillating pulse modulator comprises rescue means and mode detecting means and wherein said rescue means suppresses or cancels unwanted modes detected by said mode detecting means.

62. High-mode self-oscillating pulse modulator according to claim 36, wherein said modulator forms part of a multi-channel modulator circuitry and wherein the switching frequency of the modulators are synchronized, either in a mutual synchronization or in relation to a common switching frequency reference.
